(19) United States
(12) Patent Application Publication
(10) Pub. No.: US 2016/0109865 A1
(43) Pub. Date: Apr. 21, 2016

(54) System for Independent Remote Monitoring and Intelligent Analysis and Processing of Variables in Buildings

(71) Applicants: Antonio BORJORGES RODRÍGUEZ, Mexico City (MX); José RODRÍGUEZ CALIXTO, Mexico City (MX); Marisol Vianey CONTRERAS INCLÁN, Mexico City (MX)

(72) Inventors: Antonio Bojorges Rodríguez, Mexico City (MX); José Rodríguez Calixto, Mexico City (MX); Marisol Vianey Contreras Inclán, Mexico City (MX)

(21) Appl. No.: 14/894,811

(22) PCT Filed: May 29, 2014
(86) PCT No.: PCT/MX2014/000081

§ 371 Date: Nov. 30, 2015

(30) Foreign Application Priority Data
May 31, 2013 (MX) MX/A/2013/006139

(51) Int. Cl. G05B 15/02; G01R 21/133

(52) U.S. Cl. CPC G05B 15/02; G01R 21/133

(57) ABSTRACT

The present invention relates to a system for independent remote monitoring analysis and intelligent processing of variables in buildings; the system also provides an interface that can be consulted via mobile devices or internet on a desktop computer; the present invention allows the autonomous generating of solutions to changes in variables such as electrical energy consumption, temperature, humidity, level of lighting and concentration of gases, among other variables that contribute to the efficiency of the building, as well as the comfort of the users inside.

### FIELD OF THE INVENTION

The present invention pertains to the field of telecommunications, electronics, the field of management systems for buildings, information technologies, and sustainability. Specifically, the present invention relates to a system for remote monitoring and control of variables in buildings, intelligent analysis and processing, and autonomous generation of solutions.

### BACKGROUND OF THE INVENTION

Currently, approximately 45% of energy consumption in the world corresponds to construction, operation and maintenance of buildings. Mexico has an urban population of 76%, which largely represents the importance that the use of energy has in the country's development.

The work required to reduce and make more efficient such consumptions is an issue that should be addressed in the national and international agenda in the years to come. Proof of this is the recent diversification and increased number of projects and companies related to sustainability and energy saving solutions. Likewise, the growing interests in energy efficiency certifications for buildings, like LEED in the US, BREEAM in Europe and even in Mexico City with the PCES program of the Federal District's government. These programs, companies, and certifications are dictating the trend in energy savings and efficiency for buildings.

A serious problem existing in many of the commercial buildings nowadays is the lack of data about the things on which more energy is consumed. About 60% of the energy consumption in an average commercial building results from air conditioners and/or heating. Users, owners and persons in charge of the maintenance of buildings in Mexico usually do not have the tools needed to know their electric power consumptions disaggregated, and much less know how to solve the problem.

This lack of knowledge and tools causes high energy costs for buildings, and a reduction in its economic growth, which directly affects the country's growth. At the same time, the amount of electrical energy consumed increases, which directly reflects an increase in the emission of greenhouse gases, spending of fuel and natural resources.

For the same reasons new energy savings programs have been incentivized, both privately and on the part of government. There are laws and regulations for savings and efficiency in energy consumption: in Mexico, for example, there is the Law for Sustainable Use of Energy or the Official Mexican Standard (NOM) 008 or NOM-020, which deal with energy efficiency of buildings.

This is not a new issue, and some solutions have already been developed that in certain way prevent excessive energy consumption. The need of sustainable use of energy for owners, as well as operators and users of buildings, for which energy use generates a significant expense in its operation, has incentivized and motivated the development of some systems that to some extent, and with certain restrictions, address the excessive use of energy.

The most simple way for knowing energy consumption, and also widely available is found in the electric service provider. In the case of Mexico, the Federal Electricity Commission keeps track of energy consumption in kW and kWh of all energy users. There is a general measurement of the consumption of the entire building, or according to the meters existing. Similarly, there is a history of measurements done throughout the year or a 2-year period.

This type of measurement can provide some information, but is not enough to give tools for saving, since the amount of energy used by each equipment or operative area in the building is not specified.

In most of the buildings there is a department in charge of maintenance and operation of the facilities. This department can identify consumptions and make measurements in each area or equipment critical for the operation of the building. By these studies certain solutions to regular energy use can be found. The problem is that it is a complex method that not always can be carried out by any building maintenance department, and also the samples taken may represent or not the total use of energy in the building.

The persons in charge of maintenance then rely in external consultants, experts in electrical measurements or energy diagnostics. The external consultants then make exhaustive measurements on every equipment, apparatus and contact plugged in the building to make a map of energy consumption in the building. Besides the high cost of a similar study (depending on each consulting firm), it is not carried out periodically, so not always are detected operational problems, such as prevention of wear on pumping equipment or compressors. To find appropriate solutions to the normal operation of each building it is necessary a periodic or continuous monitoring of consumptions.

There is also equipment for a continuous and dedicated measurement of energy. These equipment are connected to different points in the building to make a continuous monitoring of consumptions and to find patterns and suitable solutions for each area. These systems may be interconnected or not to each other to communicate the information. The interconnections are made wired, by means of the local network of the building, which gives independence to the maintenance department regarding the system, as well as regarding other systems or computing. The responsibilities are divided.

Some systems are connected wirelessly, but also need to be connected to the local network of the building, or at least to have a central processing unit (such as a server) in the computing area of the building. In general these systems are only for information, and do not generate any purposed solution, nor identify consumption patterns in each area.

Usually wireless solutions for monitoring that have some monitoring capability of consumption in the building and can be accessed remotely, are solutions that require an important investment in energy measurement equipment, communications infrastructure, storage servers and a costly consulting service for monitoring, as well as proprietary software licenses. Furthermore, if the measurement of other variables such as temperature is required, an investment in new devices and complex equipment for communication between systems must be done.

Thus, document U.S. Pat. No. 8,155,900 relates to a method and system that provides information regarding energy consumption in buildings, which allows the identification of specific areas within the building that could have problems of energy efficiency. However, this system requires communication with a meter of the energy distributor company, since this system has not his own power meter or sensor; also the system disclosed in said document requires a connection with a computer, and the graphical interface is stored in the same computer, requires communication with the control systems of the air conditioning, and does not describe the measurement of parameters such as the level of lighting or CO₂ concentration.

Document U.S. Pat. No. 5,510,975 relates to a home automation system, the system implements different actions to be modified, said operations are carried out using a set of rules depending on inputs received. However, such invention also requires of a computer connected to the interface.

Document U.S. Pat. No. 7,415,310 relates to a system for intelligent management of energy in a new or old building, by means of a server or a set thereof the monitoring of data from those sensors can be carried out. Nevertheless, such system requires a server connected to the sensors' network.

Likewise, document U.S. Pat. No. 8,334,784 discloses methods to determine the source of the electric consumption of diverse equipment by the analysis of noise in the electrical signal. The determination of the origin of the electric consumption can be given on an equipment located in a central server, where the information of the electrical consumption is obtained through a sensor in the building where the monitoring system was implemented; such document does not describe the use of communication between systems nor measurement of other variables besides electricity.

Finally, document U.S. Pat. No. 8,350,694 suggests the use of a system of equipment connected in a local communication network, and the monitoring equipment connected to the same local network.

### SUMMARY OF THE INVENTION

Therefore, an object of the present invention is to provide a system of independent monitoring and remote control in buildings, which can provide the administrator or user of the building efficient and proven solutions to save energy. Furthermore, the system of the present invention allows having relevant information about energy consumption, serving as a base in decision making on solutions for saving; and direct comparisons with efficient buildings, establishing a goal for the possible level of efficiency for buildings considered.

Also an object of the present invention is to provide a system for independent remote monitoring in buildings that measures the electric power consumption, temperature, humidity, lighting level and concentration of gases, among other variables that contribute to energy efficiency of the building, as well as users comfort inside.

A further object of the present invention is to provide a system for independent remote monitoring in buildings, which also allows the comparison of energy efficiency index of the building compared to similar buildings, in order to know the current status and set parameters of saving and reduction of consumption.

Also an object of the present invention is to provide a system for independent remote monitoring in buildings, which also has one or more meters, depending on the number of floors.

Furthermore, another object of the present invention is to provide a system for independent remote monitoring in buildings, which uses an interface that can be accessed on a website or mobile application as it is on the internet; also the communication of the system of the present invention is not point to point but meshed internally and does not require an external gateway.

A further object of the present invention is to provide a system for independent remote monitoring, which uses neural networks or data mining for processing and analyzing information.

### BRIEF DESCRIPTION OF THE FIGURES OF THE INVENTION

FIG. 1 relates to a block diagram of the steps comprised by the system in accordance to the present invention.

FIG. 2 shows a diagram regarding the communication in a RF local wireless mesh network in accordance to the present invention.

FIG. 3 shows a block diagram of the steps of the acquisition and prosecution service, to process and display the information to the user, in accordance with the present invention.

FIG. 4 relates to a scheme of functioning of a neuronal network, in accordance to the prior art.

FIG. 5 relates to a diagram of the whole functioning of the system in accordance to the present invention.

### DETAILED DESCRIPTION OF THE INVENTION

The present invention refers to a system of independent monitoring and remote control in buildings, which can provide the administrator or user of the building with efficient and proven solutions to save energy. It also provides relevant information about power consumption to serve as a base in decision making on saving solutions; as well as for direct comparisons with efficient buildings to establish a goal for the possible level of efficiency in buildings considered.

In accordance to the present invention, the system can measure physical variables, such as power consumption, temperature, humidity, lighting level, and concentration of gases (CO₂), among other variables that contribute to the energy efficiency of the building, as well as the comfort of users inside. In this way, electric power is the most representative variable, as it is measured to know the real-time consumption in each area of the building, and thus provide clear data regarding efficiency.

Temperature and humidity are measured to keep the building in a comfortable environment in normal operation with optimal use of energy, according to theories of thermal comfort inside buildings; temperature and humidity inside the building play a very important role in determining saving solutions and energy costs reduction.

Similarly, lighting has a determinant weight in energy consumption in a building; therefore the measurement of lighting level is directly related to energy consumption. The right lighting level is determined according to predetermined parameters and standards related to the operation of the building, and based on these standards the system detects a suitable level of lighting and determines whether the consumption is efficient.

In a first aspect of the invention, the system performs a data acquisition step, said step is achieved by using two different measuring devices. The first device (A) acquires and measures the power consumed; the second device (B) measures the variables temperature, humidity, lighting level and CO₂ concentration. Preferably, the electric power measuring device (A) is placed in the electrical room in each floor of the building, and is able to measure the energy consumed across the floor at the same time. Preferably, the environmental variables measuring device (B) is placed in different areas inside the building in the space occupied by users. Both devices are placed in spaces of approximately 75 m² each for being able to determine the state of the environment in every occupied area. This will be explained in detail later.

In accordance to the present invention, both the device (A) and the device (B) can be one or more, depending on the needs and conditions of the building.

In accordance to the present invention, both devices comprise in turn seven main steps:

Feeding

Detection (sensors)

Coupling

Processing

Communication

Memory

Control

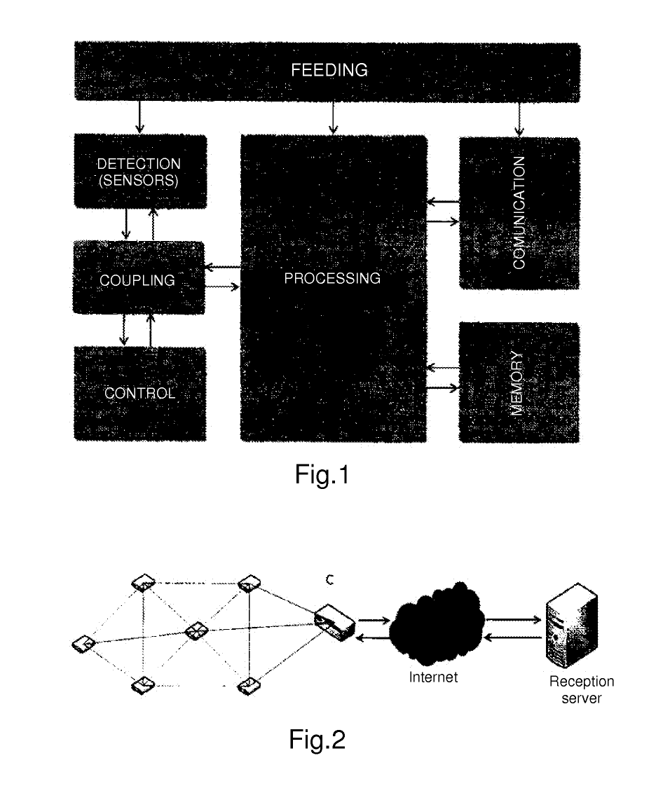

FIG. 1 shows a block diagram of the above-described steps.

In the step of feeding the input voltage is adjusted in order to supply the energy needed for each of the subsequent steps. Feeding is different for each device, and depends on the voltage level required by each of them. The electric power measuring device (A) is fed from the same supply circuit that the panel(s) it monitors; supply may be between 110 Volts to 230 Volts. In this case, it is considered a power source that converts alternating current to direct current, and can receive an input from 90 Volts to 277 Volts AC. The output is in direct current according to the needs of the processes described below for powering the electronics for acquisition and processing. The measuring device (A) has a low power consumption and protective insulation to prevent damage to the circuit board; it also has protection against short circuits, which provides highly reliable protection.

The environmental variables measuring device (B), on the other hand, is powered from a rechargeable battery that will have a stable and considerable duration. The battery provides a supply voltage different than necessary for the components; thus a voltage regulator which allows feeding the electronics for acquisition, processing and communication is also provided.

In another aspect of the invention, the electric power measuring device (A) is placed in the electrical room of each floor, so that it can measure the electrical power consumed by each panel in the floor. This measurement is based on sensors for acquisition of electric power. These are high-tech sensors, and they need an input voltage and current for each phase, to deliver the electrical power consumption and the power factor of the measurements.

The measuring device (A) comprises an acquisition module, which is split in two main parts: the acquisition of the physical signal to be measured, and the unit that processes the data for coding it into an understandable value for the processing step. The acquisition and conditioning of the signal is performed using a filtering and correction circuit, which prepares the signal to be processed by the acquisition step. At the end of the circuit, it is delivered to a processor that makes the acquisition of data, processes and converts them into digital data. This part is deemed as acquisition, because the component only obtains the signals and convert them into a real value. For example, it receives voltage and current from each phase, and can convert them into different types of power consumed by the equipment that is being monitored, such as reactive, apparent and real, and also can obtain its three-phase power factor.

The sensor that measures electric power, in turn, sends the information obtained through a communication protocol to the processing module. The component has a low error range, effective communication with the processing modules, and low power consumption.

Table 1 describes the characteristics of the acquisition module of the measuring device (A).

TABLE 1
Characteristics of the electric power acquisition
component

| | |
|---|---|
| Phases | 3 |
| Configurations | Star (3 or 4 wires), Delta |
| Measurements | RMS voltages and currents |
| | Active, reactive and apparent powers |
| | Power factor |
| | Total harmonic distortion (THD) |
| | Frequency |

According to the present invention, the measuring device

(A) further comprises a processing module, which receives signals of varying electric power to be converted to digital signals, and be sent via a communication module. For processing, a processing component that is capable of communicating with the acquisition module is used, and also it verifies the acquired data, sends control signals to the communication module, and shows the details of each function of its program on an optional display.

As shown in FIG. 1, communication between acquiring and processing requires a step of signal coupling. In this step there is a component for signal isolation communicating both stages, that is, a component with bidirectional communication.

Afterwards, during the memory step, the measuring device (A), which also has a high-capacity external card to store the information acquired by all the devices connected thereto, stores the data acquired with their respective date and time as a backup in the event of communication failure with the network. Thus, the measuring device (A) sends the information that has been acquired and processed to the network via a communication module. This module is controlled by the processing module previously described to handle deliveries and to determine the address to which data is sent. Within the network of measuring devices, a radio frequency wireless communication module is used, and a wireless communication module is used for internet connectivity to the local network.

The wireless communication module is controlled by communication with the processing module, which sends control data serially and determines the time required to send information and the address thereof. Once the information is sent, confirmation of the server is expected, indicating that it has been received successfully; otherwise it will be sent again or stored.

In another aspect of the invention, the environmental variables measuring equipment (B) is placed in areas occupied by users, thus achieving environmental measurements. Each of said measuring device (B) has a plurality of sensors according to user needs, which measure the ambient temperature of the area, the relative humidity, the amount or level of lighting and the concentration of CO₂ in the environment. These sensors receive the physical signal of each of the variables acquired, and converts them into an electrical signal. Thus, the signal can be translated, coupled and processed by the system.

The signals delivered by the sensors, depending on each one, must be coupled to be properly processed by the device. The coupling is to adjust the output voltage or current signals from each sensor to be read to the input level of the processing step.

Thus, once fed the measuring device (B), the plurality of sensors that measure temperature, humidity, lighting and CO₂ perform the acquisition of variables.

Each of the sensors has a different connectivity and operation. The temperature and humidity sensor works by measuring the relative humidity and ambient temperature. It has a precision that is adjusted according to the needs of the user and the operation carried out; for example it can have an precision of ±4.5% for relative humidity and ±0.5° C. for temperature, and a range of operation from 0 to 100% in relative humidity and from 0 to 70° C. in temperature; it is low power consumption and has connectivity to the processing in the same communication protocol. Typically it is used for environmental conditions.

To measure lighting, a digital photosensor or any other type of sensor to measure this variable is used. The sensor converts the light intensity into a digital signal that can be read and processed by the microcontroller. It delivers an output approximated to the response of a human eye, in lux. If said sensor delivers a digital signal, it does not require a step of digital-analog conversion, otherwise the step of analog conversion is required.

Also, a CO₂ sensor is used to determine the concentration of the gas, and estimate the users in the area being measured each time. The sensor measures the parts per million of carbon dioxide present in the environment, has a range according to the needs of the user and the operation carried out, for example 2,000, 5,000, or 10,000 ppm of CO₂. It also is low power consumption and is also used in control systems for air conditioning. It has a precision according to the user needs and the operation carried out, for example, from ±50 ppm, or 3% of the reading.

In accordance to the present invention, the measuring device (B) comprises a processor to concentrate the measurement of variables during the storage step; said processor is a microcontroller that receives data transmitted from each sensor to verify and prepare them for being sent during the step of communication. It also decides and controls how and where the data is sent, as well as the identification of valid data or failures in wireless communication. The communication protocol using measuring equipment (B) may be an I2C or other protocol, and wireless communication may be by a local radiofrequency network or another, since the devices will be connected to each other, sending the information to a device for concentration and connection to Internet, which is the electric power meter.

According to the invention, the measuring device (B) comprises a communication module, if communication is wireless, the module may comprise a radio frequency communication card based on the Zigbee technology or other.

Next is extensively detailed the use and installation of measuring devices (A and B). In this sense, these devices are placed in different parts of the building, according to its application and the variables being measured.

Thus, in the case of the electric power measuring device (A), the equipment must be installed in the electrical room in each floor of the building. This way an electric measurement for each floor or area of the building is provided; for example in a building that on the same floor has cafeteria, laundry areas, etc., where is required to measure each, several metering devices of this kind would be placed in each supply panel of the area. This serves to make comparisons by floor and area, and to find out where are the most important consumptions.

Measuring the energy consumption of the panel or the floor requires measuring the voltage and electric current passing through the power supply circuit of the panel.

Measurement of electric current is performed with any type of transducer of electric current measurement, for example transformers connected to each of the phases of the panel. Typically they are three-phase panels that distribute the energy consumption to the devices and apparatuses connected around the floor. Each current transformer converts the electromagnetic signal of the current flowing over the wire to a voltage measurable by the device. The voltage measurement is made by cables directly connected to the voltage outputs of the panel to be converted by the rectification circuit and is adjusted to an equally measurable voltage by the acquisition component.

According to the electrical layout of the building and each floor, the need to place one or more electrical measuring devices is analyzed on each floor. Ideally there will be a meter per floor, unless the load connected to the floor requires placing more meters.

Furthermore, the environmental variables measuring equipment (B) is installed on major work areas inside the building, which are chosen according to the number of people who use such areas and the time they are there, as well as the deviation of values that each of the variables may have. It is placed in open spaces and areas with access to each variable, as could be at the top of the area, placed on the roof or a wall that has visibility to the whole space. Each sensor that acquires the tag is placed within the device, but has spaces so as not to obstruct the acquisition of the signals and attributes, such as temperature or lighting.

The two types of measurement equipment (A and B) have wireless communication modules, which communicate with each other so that the information is sent to the server on the Internet. Communication is a radiofrequency local mesh network (FIG. 2) by which all computers are connected. The measuring device (A) will concentrate the information of other devices and will serve as an input and output gate for information to the global network, because it has another communication module on Wi-Fi, GPRS or any other protocol that sends information to Internet.

As shown in FIG. 2, the environmental variables measuring device (B) are interconnected to communicate information regardless of the range to the hub. Information jumps from one device to another finding the route to the hub (1), simply having to ensure that there is always at least one device in the range of reach of another. When the information from each meter arrives to the hub, this is responsible for sending it to the cloud to the receiving server.

Each meter sends on the network an identifier of the meter and the measurement values. The concentrator measuring device (A) records the date and time of the measurement and then sends each data with the identifier of its respective module, network, floor, and user.

In a further aspect of the invention, a service for acquisition and processing is provided so that, once the variables of the building have been acquired and communicated, the information can be received, stored, processed and displayed to the user. This service is connected to the Internet to receive data from the network of each building, to record and analyze data independently. This data is displayed to the user by a graphical interface that the user can access in any computer (mobile or desktop) with any internet connection.

This service is comprised of 5 steps:

Information control

Storage

Processing and analysis

Connectivity service

Graphical interface

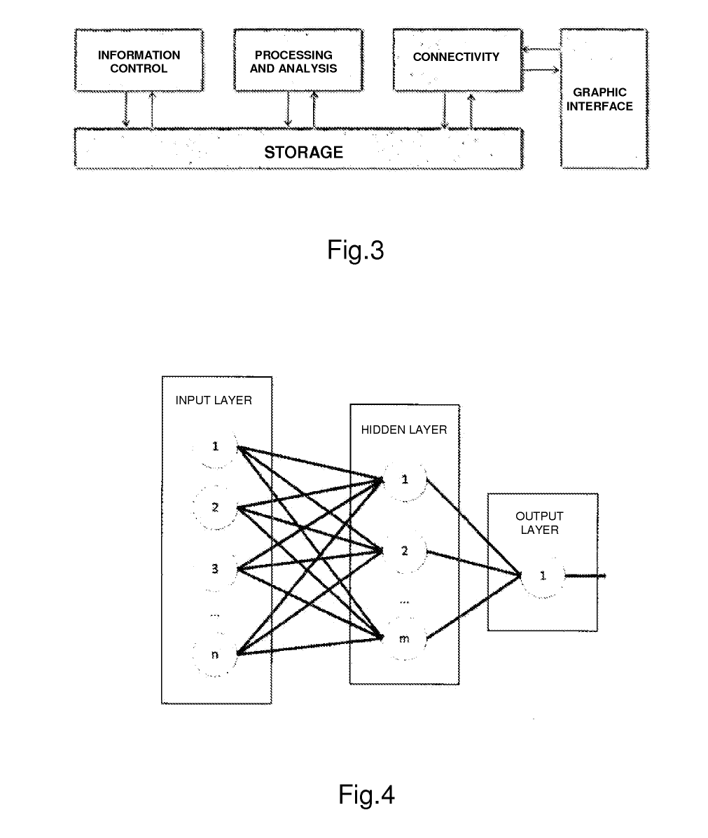

FIG. 3 shows a block diagram of the steps of the acquisition service and prosecution, to process and display the information to the user.

Each step has a specific and specialized programming to meet the needs that arise. The service has been developed so as to have data flexibility and scalability from the beginning, since quickly handles a lot of data that needs to be distributed efficiently.

For the control information step a link under a data communication protocol is designed, for example, a TCP/IP protocol that connects the measuring devices (A and B) directly with the information control module in the service. This information control module is programmed in a server that makes a load balance to distribute data received on different processing servers, which will depend on the amount of data to be processed. This data reception is made when the IP address to which packets of each measurement module are addressed is made public, being that all of them point to the same direction. The addressing is controlled through a URL or domain, which facilitates scalability; because if at some point the numeric address of the server changes, it is only needed moving the domain to the new address, for all measurement modules continue sending the information correctly.

As well, the service also has a communication protocol, such as a TCP connection socket for each module that requests sending data to the server, this is a bidirectional socket, and in each connection checks whether there are data to be sent to the module, as well as whether the data sent have been received. In the data package the address of the module that sends the data is specified, as well as the identifier of the module that receipts the information. In the same package, besides the identifier arrive the measurement values, the date and time of the measurement, and, eventually, the state of the battery. Once the transmission of data is complete, the socket is closed for having bandwidth available to other modules. Many sockets as needed will be opened, according to the number of modules that are requesting information.

The information control module acts as service on the server, running as a hidden process in the system, and has multiple threads occupying different functions.

The storage is done by a relational database, programmed in a server as a storage, and that is connected to processing servers via the same network. This database is initially in a SQL database, which is a sufficiently recognized and operated system for managing information. The tables programmed in the database relate to each other through different key columns, such as the user ID, the identifier of the equipment or the date and time of measurement. In this storage module will be stored different types of data. One of them is raw data, the data being issued directly by the measuring devices and without any processing. The information stored of efficient buildings, gathered from other studies, partnerships with research institutions or centers, among others, will occupy other type of data, which are managed independently from the process of information control of the acquisition modules.

Other type of data is managed by the processing and analysis module, which gives the breakdown of consumption information, comparisons between months in the same building and other buildings, as well as proposals for solutions found. Finally, the type of data managed by the service of connectivity to the graphic interface, which necessarily has a much more transparent organization that is easily identified for each stage of the graphical interface.

Given this, the acquisition of data coming from the measuring devices (A and B) is performed by the information control step. In this step there is a service or software for acquisition, with which the information is received while data transfers are made to control or make changes to the settings of each measuring equipment. In this step a direct and bidirectional connection exists with the measuring devices having Internet connectivity.

After the acquisition of information has been made, the system stores the data so that other services can access the information acquired, and can communicate the changes between services. For example, the information control service will obtain from the storing system the information necessary to transmit signals of control or configuration change to every measuring device with which has connectivity in each building.

The processing of data is done at the stage of processing and analysis. This stage mainly performs three functions: identifying patterns and breakdown of energy consumption; obtaining and comparing energy consumption index; and identifying solutions.

These functions determine the correct operation of all the solution, so this step is essential in the monitoring system object of the present invention.

Since the information of power consumption is obtained generally from each floor of the building, the system provides a function for identifying patterns and breakdown of energy consumption, in this way is possible to know how power is consumed in each area of the building to find certain patterns in its use, and when comparing them with a database of average consumption patterns, a breakdown by areas or type of consumption is obtained.

For example, on a floor of a building there are different types of consumption, such as air conditioning, contacts, computer equipment, lighting, among others. The electric power measuring equipment (A) sends the overall consumption of the floor, and the information generated is used also by the environmental variables meters (B) to know what proportion of the energy is consumed by each type of consumption, as might be 60% of consumption in the air conditioning, 20% in lighting and 20% in the computer equipment. This is done by analyzing the consumption patterns of each building, and comparing them with established patterns, depending on the type of building, its use and climatic zone.

Once the type of consumption has been identified, the building should get certain index of energy consumption, which depends on the total consumption of the building vs. its size or occupied area. This index is used to identify accurately the efficiency of the building analyzed. The index can be measured in kilowatt per square meter (kW/m²) or any other unit that allows for a comparison with other similar buildings. From a database of buildings with low consumption rate, the comparison with the buildings analyzed is based on different variables of the building, such as its use, size, and climate zone, to learn how consumption might behave and where are the largest potential savings.

If the comparison of the rate of consumption has been done, and the biggest areas of opportunity to generate savings of consumption in the building are known, the function of identifying solutions to obtain concrete actions that have a direct impact on reducing energy consumption and therefore generate savings in the payment of electricity and promote the efficiency of the building is needed. To identify solutions, the investment and the time required for return of investment are also known.

All functions of the processing and analysis step are managed with data obtained from storage, and at the same time, processed data is also stored so that the other steps of the system can read the information.

To do the necessary functions in the step of processing and analysis, such as the breakdown of energy consumption, or comparisons of levels of efficiency and proposed solutions, making a high information processing is required. For this data management, the system of the present invention provides two solutions that achieve an identification of patterns efficient enough to find the kind of consumption that is made, and to find the most efficient solutions in cost/benefit to the building, and that also are tested in other buildings of the same type; i.e., data mining and neural network programming, for example.

Neural networks must be “trained” by a large amount of data indicating how the expected behavior of the building is. Likewise, data mining is based on a sufficiently large quantity of data to find optimal consumption patterns in the list of buildings identified as similar to the building being analyzed. FIG. 4 shows a scheme of the operation of a neural network. This Figure shows the data inputs to the neural network and how the necessary connections are made according to the trained pattern for the network.

Likewise, the data mining system needs a significant amount of important information for generating a pattern of consumption information for new buildings. This amount of information may be obtained from the partnerships mentioned, and from the same buildings measured and stored in the same database.

During the step of connectivity service, the system obtains data from storage and prepares them so the graphical interface can read them. Likewise, it receives information from the graphic interface, which must be able to communicate with the storage, so that in both steps of processing and analysis, such as information control, data that the user has sent through the graphical interface can be accessed. Generally speaking, this is a service of translation or decoding of messages between the database and the graphical interface. The connectivity service is programmed so that it is easily accessible by all platforms on which there is a graphical interface. Also is performed the acquisition of information that comes from the graphical interface, which is in turn dictated by the user. This information is also passed to the database to be stored and used in the step of information control to be sent to the metering modules.

Finally; in the graphical interface, the user has the ability to get information sent by the measuring devices, as well as the information processed by the service. The interface consists of a data summary by building, in which the overall energy consumption index, and the target index are displayed. It also has the option of observing the consumption history of each measuring device. As previously mentioned, the graphical interface can be visualized in native mobile applications, for example for iOS® systems in the phone and tablet versions, and the Android® system, also in the phone and tablet versions.

According to the present invention, the interface consists of 5 main screens showing general information of the building, the information generated in real time for each measuring device, the measurement history, the comparison of bills of energy consumption, the comparison of consumption between months of the same building and against other efficient buildings, proposed solutions and their return on investment, and finally general system settings.

The interface also has the ability to make comparisons with the energy bill, as the system is able to generate a receipt for consumption and compare when, how, and why energy has been consumed. This is an energy bill with much more information, detailing the consumption in the period. It is also possible to see the solutions proposed by the system, as well as the required investment and the time for return of investment. Likewise, the system issues notifications depending on consumption levels, goals and other user settings. The information is obtained thanks to the proposed solutions resulting from the step of processing and analysis.

Referring to this, the user will have the necessary information obtained from measuring devices (A and B) to achieve lower energy consumption based on specific actions, and can be as simple as a change of habit or operation, or as complex as an architectural implementation that generates benefits attractive enough to be technically, economically and environmentally convenient.

In a further aspect of the invention, the information generated from measurements of each building is compared with a database generated mainly for obtaining three types of information:

Information for the breakdown of energy consumption

Information for comparison of energy consumption indexes

Information for generating solutions

Each of these types of information will be obtained from the database of buildings, which includes data on international investigations, companies with open access to information, as well as important alliances with research centers or institutions with studies in energy efficiency and different ways of obtaining information. In addition, measurements of each building also feed the database with data measured regularly with this solution, creating a base in constant growth and continuous improvement.

Thus, the information for the breakdown of energy consumption is to know details of consumption of buildings, where is specified how much is each of the types of consumption in a building, mainly air conditioning, lighting, computer equipment, and other. Based on this information an analysis of each building to be measured can be done, and also a comparison of consumption to find the patterns identified by the details of consumption of the database of buildings.

These buildings also have a way to know the energy consumption index, which will serve as a comparison with the index obtained from the building measured in each case. This index provides a synthesis on the general state of the building and of the greatest areas of opportunity, after generating also information on the breakdown of types of consumption.

The database also provides information about solutions implemented in efficient buildings, so that these solutions already tested and implemented by experts in each circuit are directly analyzed for use in the destination building where the measurement is made. By implementing proven solutions, the building has top level information on how to take advantage of the opportunity areas directly and optimize directly the energy consumption. These solutions, which will be described later, can be automatic control systems of the connected equipment as well as bioclimatic architectural solutions that significantly reduce energy consumption.

To operate each type of information required by the database, a specific content in the database of buildings is necessary; thus the present invention distributes the data into four groups. The first group consists of the initial building information, such as the type of use (school, office, hotel, etc.), the total building area, number of floors of the building, number of people using it daily, as well as the kind of weather where the building is. This information is relevant to know the building against which is being compared, and whether or not it meets the characteristics of the building evaluated or measured.

The next group includes the breakdown of type of consumption and there are 4 main types estimated: consumption of air conditioning, consumption of lighting, consumption of computers, consumption of motors or pumps inside the building, and the “other” category. Whenever new types of consumption are identified, these will be added to the group.

The next group is the index of energy consumption, since it contains the total power consumption, the total size of the building area, and thus the total index of the building, which is the amount of energy consumed by each unit of area measured, is obtained. In this case the measure unit is kilowatt per square meter (kW/m2), or any other similar unit.

The last group consists of solutions obtained from each efficient building, which are related to hours, which means that the solution comes changing certain consumption strategies; the daily type, which can also be related to the customs of each building analyzed; involving active solution plans and campaigns regarding monthly information, as well as consumption control or architectural solutions. Each of the proposed solutions estimates the investment needed for the project.

In addition to the uses and customs that can be modified in energy consumption of the building, also are stored control solutions, which may consist of automatically controlling the lighting of some luminaries, controlling the turning on or starting of air conditioners or water pumping, as well as other types of automated controls. Likewise, bioclimatic architectural solutions already tested and implemented in efficient buildings of the sample are also stored. The architectural solutions range from protection of facades, crosswind implementations, air movement, etc.

When as much information as possible is accumulated in these four tables, it is considered that the implementation of the proposals generated by the system in the building will be proportionally less expensive, more economical and faster.

Also, the information stored in the database is useful to make efficiency comparisons to other buildings, to find patterns of consumption in the analyzed building and to propose achievable and measurable goals. The analysis of the building is largely thanks to the information collected in the efficiency database.

As described above, the system for monitoring and intelligent processing of variables of the present invention integrates the measuring devices (A and B), the service and the accumulated knowledge of the efficiency database. To accomplish the collaborative job between different areas of technology, bioclimatic and statistics, the solution of the present invention largely manages to generate energy efficiency in buildings.

Being able to measure different variables, the system acquires the information needed to make a diagnosis of the building in real time, and to know the behavior of energy over an established period of time.

From the acquired information, the system collects, stores, and processes the information for being deployed. This process is done by a secondary service that identifies consumption patterns, proposes solutions and displays all information in a graphical interface for being accessed online. This secondary service is in the cloud and is easily scalable, depending on the amount of existing measuring devices.

Processing information is compared with a vast database of efficient buildings, collected through various ways, such as partnerships with institutions, research, among others. This information is validated by international experts for analysis, and is the information which gives validity to the solutions and proposals provided by the present invention. The data includes expected patterns of energy consumption, external and internal conditions of buildings and implemented and tested solutions in each of them.

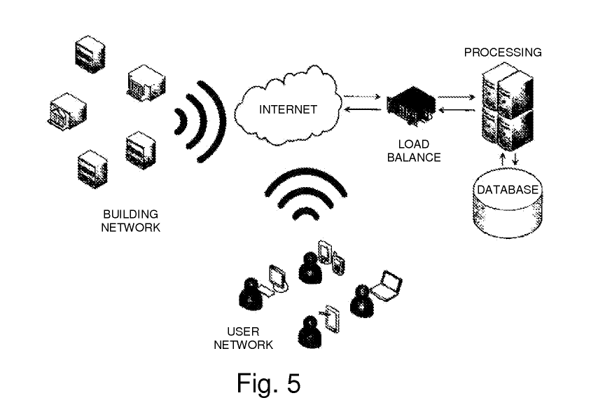

By integrating each of these stages, the system can identify the greatest areas of opportunity and generates solutions with optimum return of investment. FIG. 5 shows a diagram of the complete operation of the system object of the present invention.

In view of the above, the present invention provides immediate solutions which are directly related to the customs of the operation and building users. That is, changes in the way certain routines or maintenance in the building are done, which directly affect the way in which energy is consumed.

Such solutions are identified through the analysis of the measurements of energy and environmental variables. For example, a pattern of lighting consumption, which repeatedly is done at certain time of the day, is identified in certain level of a building, where the lighting level meter indicates that it is not necessary to switch on an artificial light. In this case, it is recommended to make a change in the operation of the building to not turn on the artificial lighting at that particular time, and making this modification will generate savings.

This type of solutions can be identified directly by the types of consumption made in the building. This type of solutions can be identified directly by the types of consumption made in the building, i.e.:

Solutions for lighting

Solutions for air conditioning

Solution for computers

Solutions for motors and pumping equipment

The present invention is not limited in any way to the solutions described above, they are mentioned only as examples.

The solutions for lighting, as mentioned in the above example, refer to changes in the way the use of artificial lighting inside the building is made. Usually they refer to unnecessary use of artificial lamps, and lighting can be compensated with the necessary natural light from outside. This solution is identified through the energy meter that characterizes the use of energy in lighting, and the environmental variables meter, which identifies the level of illumination in each area of the building. In addition, the location of the building, the time of day in which this consumption is done, and the use that is given to the lighting, are also involved.

For solutions for air conditioning, the energy consumed by air conditioning equipment is also identified, and a comparison with measurements of variables such as temperature and humidity of the specified areas in the building is done. In this way consumption patterns in which the use of air conditioning may not be needed are known, and user comfort is maintained. For example, the use of air conditioning equipment could not be necessary when there are no users inside, which is something that the CO₂ concentration meter can determine. If there are no users, it is not required to turn on the equipment. Similarly, if the temperature level is lower than the level of comfort, the air conditioning may not be necessary in the specific area.

Computers are important energy consumers in buildings such as offices or schools. These equipment are used to perform a specific function by users. If energy use from this type of equipment is identified at a time in which there are no users in the building, or by the CO₂ concentration meter is determined that there is no one in the room or zone where computer equipment consumption is done, it is recommended not to use this equipment, so that no energy is consumed unnecessarily when there is no one to perform functions on the computer.

Pumping equipment or motors usually are another great energy consumer in buildings. Because they need a lot of energy to operate, it is required an efficient use and a proper maintenance so that the equipment do not consume unnecessary energy. It is common to turn on pumping equipment at times when energy can have a higher cost, depending on the rate, and a higher payment is made when the operation is not necessary. It can also be prevented the switching on of several motors at the same time, which also can result in an energy consumption higher than if such motors were turned on in a stepped or separated way.

There are other ways to generate immediate savings by changing habits and customs, which are dependent on each type of building and its common operations. The monitoring system object of the present invention continuously measures and diagnoses the building, which promotes a continuous and efficient identification of solutions.

The present invention also provides long-term solutions which are identified as solutions that require certain changes or investments in the building, and generate more significant savings in energy consumption in the building. The solutions are identified to be of two main types: changes in the building design, with solutions of bioclimatic architecture; or solutions that require an active control of computers. Each type of solution is analyzed in light of the required investment and savings generated.

The configuration of the system object of the present invention, described above, is provided in order to completely and thoroughly detail the scope of the invention, and transmit it to those skilled in the art; however the invention may be embodied in many different forms and should not be limited to the mode set in the present description.

Having described the invention, what is claimed as property what is contained in the following claims:

1. System for independent remote monitoring and intelligent analysis and processing of variables in buildings, characterized by comprising:
a measuring device (A) which acquire and measures the consumed electrical power and which is placed in the electrical room of each floor;
a measuring device (B) which measures temperature, humidity, lighting level and CO₂ concentration and which is placed in work areas inside the building, in open areas and in access areas for each variable;
a service for acquisition and processing to receive information, storing, processing and displaying it to the user;
a graphical interface to show the user the information delivered by the measuring devices (A and B), as well as the information processed by a secondary system; and
a data base comprising information for the breakdown of energy consumption, for comparison of consumption indexes, and for generation of solutions.

2. System according to claim 1, wherein both measuring device (A) as measuring device (B) carried out seven principal steps: feeding, detection using sensors, coupler, processing, communication, memory and control.

3. System according to claim 2, wherein measuring devices (A and B) comprises a plurality of sensors that acquires the variables, such sensors are placed inside said measuring devices (A and B), with spaces, in order to not to obstruct the acquisition of the signals and properties.

4. System according to claims 1 and 2, wherein measuring device (A) feeds from the same feeding supply of the building board or boards that monitors, the feeding can be between 110 Volts to 230 Volts, with a specific outlet for each process, for feeding the electronic of acquisition and processing; wherein:
said measuring device (A) has a low power consumption and protection insulation to avoid damages in the circuit board; likewise has protection against shortcuts, which provides highly reliable protection.

5. System according to claims 1 and 2, wherein measuring device (B) feeds from a rechargeable battery that has a significant and stable duration.

6. System according to claim 4, wherein measuring device (A) performs the measurement from sensors for acquisition of electrical power, which need a voltage and current supply in each phase to give the electrical power consumption and the power factor of the measurements.

7. System according to claim 6, wherein measuring device (A) also comprises an acquisition module which is divided in two main parts, the acquisition of the physical signal to be measured, and one unit that processes the information to encode to one compressible value for the processing step; wherein
the acquisition of the signal and conditioning it, is performed by means a circuit for filtering and correction, which prepares the signal to be processed in the step of acquisition, thus at the end of the circuit, is delivered to a processor performing the acquisition of data, processing, and converting them into digital data.

8. System according to claim 7, wherein the processor sends the information obtained to a processing module through a communication protocol; the processor has a low error range, effective communication with the processing module, and a low power consumption.

9. System according to claim 8, wherein the processing module receives varying signals of electric power to be converted into digital signals by means of a processing component and to be sent to a communication module, wherein
the processing component is able to communicate with the acquisition module, as well as it verifies the acquired data, sends control signals to the communication module and displaying the details of each program function in an optional display.

10. System according to claim 9, wherein the communication between the acquisition and the processing comprises an additional step of signal coupling by means of a bidirectional communication component.

11. System according to claim 10, wherein the measuring device (A), also comprises a high-capacity external card to store the information acquired by all the devices connected thereto during the memory step, so in case of communication failure and as a backup the data acquired are stored with date and time; wherein
the measuring device (A) sends the information that has been acquired and processed to the network via a communication module, this module is controlled by the processing component, to manage deliveries and to determine the address to which data is sent;
where within the network constituted by the measuring devices a radiofrequency wireless communication module is used, and for Internet connectivity a communication module to local network is used;
where the wireless communication module is controlled through serial communication with the microcontroller, which sends control data serially and determines the time required to send information and the address, once the information is sent, it expects confirmation of the server indicating that it has been received successfully; otherwise it will be sent again or will be stored.

12. System according to claims 1 and 2, wherein measuring device (B) is placed in the spaces occupied by users, thus achieving environmental measurements, and because it comprises each one of said measuring device (B) a plurality of sensors which are in charge for measuring the ambient temperature of the area, the relative humidity, the amount or level of lighting, and CO₂ concentration in the environment, wherein
each of the sensors has a different connectivity as well as its operation, the temperature and humidity sensor works making the measure of the relative humidity and the ambient temperature, is of low power consumption and has connectivity with the processing in the same communication protocol;
for measuring the lighting, a digital or any other type sensor is used, the sensor converts the lighting intensity into a digital signal that can be read and processed by the microcontroller, deliver an output approximated to the response of a human eye, in lux; due that this sensor already delivers a digital signal, does not require a step of digital analogic conversion;
the CO₂ sensor allows to know the concentration of gas, and estimate the users at all times in the area being measured, said sensor measures the parts per million that are of carbon dioxide in the environment, it is also low power consumption and is also used in control systems for air conditioning; wherein
said sensors receive the physical signal of each of the variables acquired and convert them into an electrical signal, thereby, the signal can be translated, coupled and processed by the system; and
the signals delivered by the sensors, depending on each of them, must be coupled to be properly processed by the equipment, wherein
the coupling consist in adjusting the voltage signals or output current of each sensor to be read at the input level of the processing step; thus, once fed the measuring device (B), the sensors perform the acquisition of the variables.

13. System according to claim 12, wherein the measuring device (B) also comprises a processor for concentrating the measurement of the variables during the step of storing, said processor consists of a microcontroller that receives data transmitted from each sensor, for verifying and preparing it for being sent during the communication step, likewise it controls how and where the data is sent, as well as the identification of a valid datum or failures in wireless communication, wherein
said processor also uses a suitable protocol, and the wireless communication can be by means of a radiofrequency local network.

14. System according to claim 13, wherein the measuring device (B) also comprises a communication module, which consists in a radiofrequency communication card.

15. System according to any of the previous claims, wherein the measuring devices (A and B) have wireless communication modules, which will communicate each other so that the information can be sent to a server on the Internet; where
the communication consists in a radiofrequency local mesh network by means of which all the devices are communicated, so the measuring device (A) concentrates the information of the other devices and acts as an information input and output gate to the global network, due that it has another communication module with a suitable protocol that sends the information to the Internet.

16. System according to claim 1, wherein the service allows the reception, storing, processing, and displaying the information to the user; and because said service is connected to the Internet to receive the data from the network of each building in order to register and analyze it autonomously, wherein
said data are displayed to the user by means of a graphical interface that can be accessed by the user from any mobile device or desktop computer and from any Internet connection.

17. System according to claim 16, wherein the service comprises five stages, i.e., information control, storing, processing and analysis, connectivity service, and graphical interface, wherein
the information control step is over a link under a data communication protocol that connects the measuring devices (A and B) directly with a module for information control of the system, wherein
the information control module is programmed on a server that performs a load balancing to distribute the received data on different processing servers, which will depend on the amount of data to be processed, this data reception is made when the IP address to which packets of each measurement module are directed is made public, so that all point to the same address, the address is controlled by means of a URL or domain, which facilitates scalability so that all measurement modules are able to continue sending the information correctly.

18. System according to claim 17, wherein the secondary system also comprises a communication protocol by each module that requests sending data to the server; wherein
in the information specifies the address of the module that is sending, as well as the identifier of the module from which the information is received; also are received the values of measurements, the date and time of the measurement, and, as appropriate, the battery state,
once the transmission of the information is completed, the communication protocol allows to close in order to have bandwidth available for other modules that are requiring information.

19. System according to claim 18, wherein the storing of the information takes place in a relational database, programmed in a server that serve as storage, and is connected to processing servers through the same network;
said database stores the data obtained directly by the measuring devices (A and B) without any processing; regarding data stored from other sources that are managed independently of the information control process of the acquisition modules; data obtained from the processing and analysis module, and data corresponding to the service for connectivity to the graphical interface.

20. System according to claim 19, wherein the acquisition of data obtained from the measuring devices (A and B) takes place by the information control step, in which the acquisition service allows receiving the information, and at the same time sending the data for control or changes to the settings of each measuring equipment, making a direct and bidirectional connection with the measuring devices having Internet connectivity; wherein
after the acquisition, the system stores the information so other services can access the information acquired, and communicate their changes between services.

21. System according to claim 20, wherein during the processing and analysis step, the secondary system performs the functions of pattern identification and breakdown of energy consumption; obtaining and comparing the energy consumption index; and identification of solutions.

22. System according to claim 21, wherein the comparison of the energy consumption is performed based in data stored in the database regarding buildings previously analyzed, the use, size and climate zone thereof; at the same time the new data generated are also stored.

23. System according to claim 22, wherein the functions of pattern identification and energy consumption breakdown; extraction and comparison of the energy consumption index and identification of solutions, are performed by means of any suitable analysis.

24. System according to claim 1, wherein the graphical interface preferably consists of 5 main screens showing, among other, general information of the building, the information generated in real time for each measuring device, the measurement history, the comparison of bills of energy consumption, the comparison of consumption between months of the same building and against other efficient buildings, proposed solutions and their return on investment, and general system settings.

25. System according to claim 24, wherein the graphical interface also allows comparisons with the energy bill, as the system is able to generate itself a receipt for consumption, and to compare where, how and why is consumed such energy;
it allows to observe the solutions proposed by the system and the required investment and the time for return of investment; and
issues notifications depending on consumption levels, goals and other user settings.

26. System according to claim 25, wherein the interface can be displayed in a mobile device or a web page in a desktop computer.

27. System according to claim 1, wherein the database contains information regarding to the breakdown of power consumption, information for comparison of energy consumption indexes, and information for generating solutions.

28. System according to claim 27, wherein the data is obtained from other analysis in different buildings and/or areas, allowing to make an efficiency comparison; and of the measurements taken at the time, to each building.

29. System according to claim 28, wherein the database allows storing data in four groups: initial information of the building, type of consumption, the index of power consumption, and issuance of solutions.
